(19) United States
(12) Patent Application Publication
(10) Pub. No.: US 2005/0028067 A1
(43) Pub. Date: Feb. 3, 2005

(54) Data with multiple sets of error correction codes

(76) Inventor: Charles R. Weirauch, Loveland, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/632,755

(22) Filed: Jul. 31, 2003

(51) Int. Cl. H04B 1/74; H04L 1/22; H02H 3/05; H05K 10/00; H03K 19/003; H03M 13/00

(52) U.S. Cl. 714/758

(57) ABSTRACT

Data is formatted into logical ECC blocks for communication or recording. For primary data in a first block, there is ECC data in the first block and additional ECC data in a second block. When the ECC data in the first and second blocks are independent, then compatible devices can use the ECC data from either block, and other devices can use the ECC data from just the first block.

### FIELD OF INVENTION

This invention relates generally to data storage and more specifically to error detection and correction.

### BACKGROUND

Computer data memory systems and data storage systems often include provisions for detecting and correcting errors. It is common for the smallest addressable unit of data to be called a sector, and it is common to further logically group multiple sectors into blocks, where each block includes error correction for the block. These logical blocks are called error correction code (ECC) blocks. For most applications, the probability that an error can remain undetected and uncorrected in an ECC block is acceptably low. However, there are sometimes requirements for an even higher assurance of data integrity. There is a need for optional additional error detection and correction in a manner that is compatible with existing standard formats.

### SUMMARY

For at least one ECC block, the data area within the ECC block includes ECC data for at least one other ECC block.

### BRIEF DESCRIPTION OF THE DRAWINGS

FIG. 1 is an example embodiment of an ECC block.

FIG. 2 illustrates an example conceptual ECC block having more ECC data than the ECC block of FIG. 1.

FIGS. 3A-3C illustrate a data track on a medium, with example alternative arrangements of auxiliary ECC blocks.

FIG. 4A is a flow chart of an example embodiment of a method.

FIG. 4B is a flow chart providing additional detail for the method of FIG. 4A for one example alternative method when reading or receiving data.

FIG. 5 is a block diagram of an example embodiment of a system.

### DETAILED DESCRIPTION

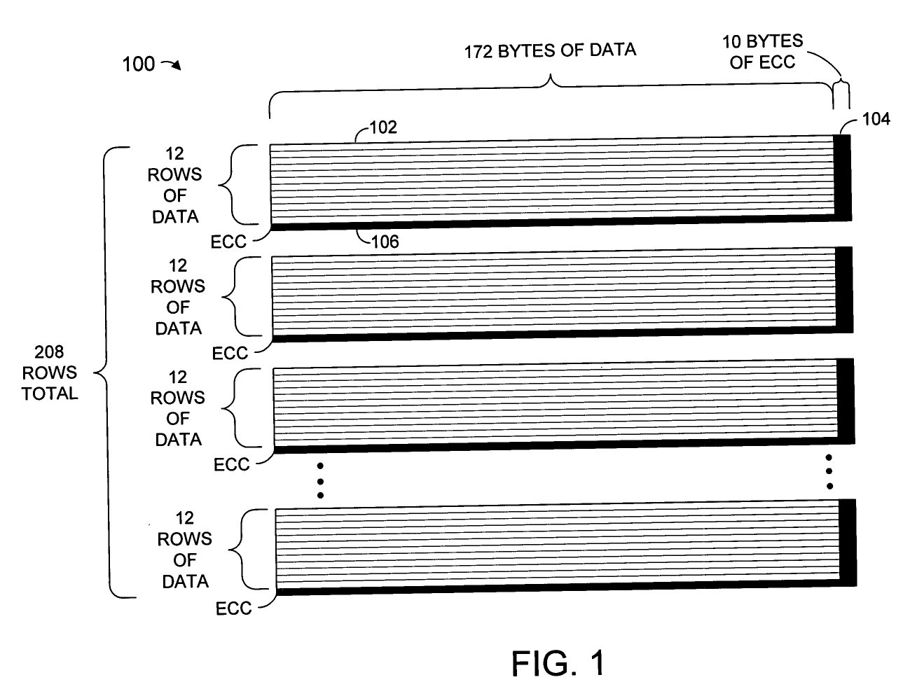

FIG. 1 illustrates an example ECC block 100, before encoding. In the example of FIG. 1, a sector (102) comprises 2,048 bytes of primary data. In some current optical disk standards, an ECC block comprises 16 sectors of primary data, as illustrated in FIG. 1. In some proposed standards, an ECC block comprises 32 sectors of primary data. In the example of FIG. 1, each sector (plus 16 bytes of identification and other overhead data) is logically formatted into 12 rows of 172 bytes. For an ECC block with 16 sectors of primary data, 16 bytes of column ECC data 106 are computed for each of the 172 columns (one byte per column) of primary data, with the resulting 16 rows of column ECC data interleaved with the rows of primary data. Ten bytes of row ECC data (104) are appended to each row of 172 bytes of primary data, and to each of the 16 rows of column ECC. For an ECC block with 16 sectors, there are 2,752 bytes of column ECC data (16 rows, 172 bytes per row), and there are 2,080 bytes of row ECC data (10 bytes per row, 12 rows per sector, 16 sectors, plus 16 rows of column ECC), for a total of 4,832 bytes of ECC data.

For at least one ECC block, at least part of the area designated as primary data (FIG. 1, 102), contains at least some ECC data for the primary data in at least one other ECC block. An ECC block containing only primary data is a “primary ECC block”, and an ECC block containing ECC data in the area designated for primary data is an “auxiliary ECC block”. Assume, for example only, 16 sectors for each ECC block, and one auxiliary ECC block for every four primary ECC blocks. Also assume that each auxiliary ECC block is substantially filled with ECC data. Each auxiliary ECC block can have up to 8,192 bytes of ECC data for each of the four associated primary ECC blocks (compared to 4,832 bytes of ECC data in each primary ECC block). Using the above example numbers, an auxiliary ECC block enables correction of about 1.7 times as many defective bits as a primary ECC block.

Having one auxiliary ECC block for every four primary ECC blocks is just one example. Even more error correction capability can be obtained by providing fewer than four primary ECC blocks for each auxiliary ECC block, including multiple auxiliary ECC blocks for each primary ECC block. In addition, it is not necessary for all the data in an auxiliary ECC block to be ECC data. For example, some of the 16 sectors of data may be ECC data, and the remaining may be primary data.

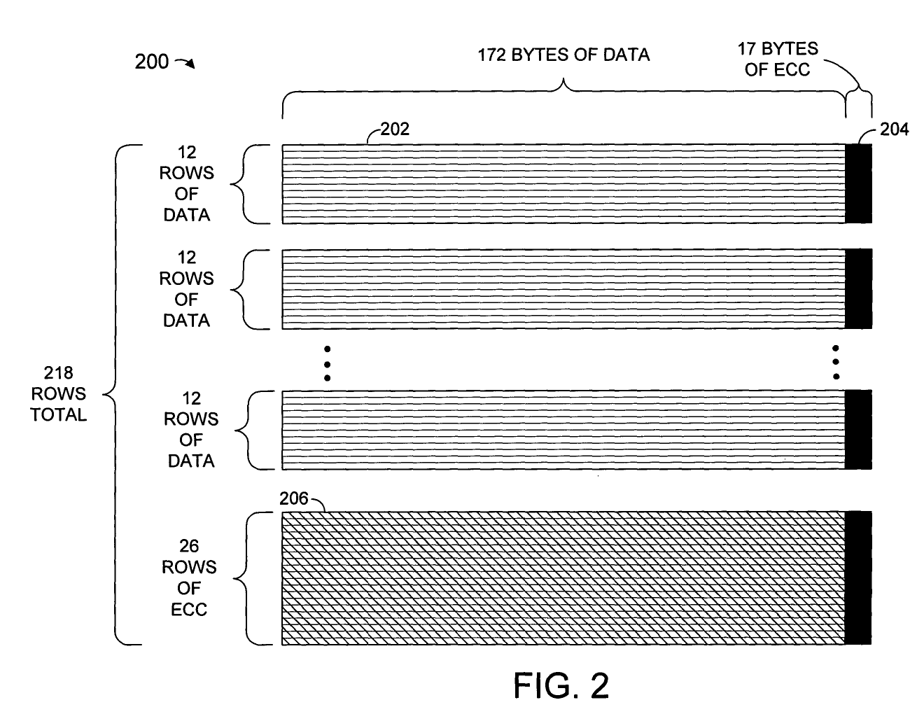

FIG. 2 illustrates a conceptual ECC block 200 (before encoding) having the number of ECC bits available in one-fourth of an auxiliary ECC block, using the assumptions in the above example. That is, FIG. 2 does not illustrate an actual ECC block, but rather illustrates the amount of primary data in a primary ECC block, along with the amount of ECC data provided by one-fourth of an auxiliary ECC block (assuming one auxiliary ECC block for four primary ECC blocks). In FIG. 2, there are 16 primary data sectors 202. Each row has 17 bytes of row ECC data (204), compared to 10 bytes in FIG. 1. There are 26 rows of column ECC data (206), compared to 16 rows of column ECC data in FIG. 1. The ECC data illustrated in FIG. 2 is physically located in the primary data area of an auxiliary ECC block, and occupies approximately one-fourth of the available primary data space. The ECC data in FIG. 2 is itself protected by other ECC data, as illustrated in FIG. 1.

Allocation, of ECC bits in an auxiliary ECC block, to primary data in a primary ECC block, is arbitrary. The following is just one example of possible ordering of ECC data in an auxiliary ECC block, based on the ECC data of FIG. 2, assuming 16 data sectors per ECC block, one auxiliary ECC block for four primary ECC blocks, and assuming that the data area in the auxiliary ECC block is substantially filled with ECC data:
Column ECC, byte column 1 (26 bytes)
Column ECC, byte column 172 (26 bytes)
Row ECC, row 1 (17 bytes)
Row ECC, row 218 (17 bytes)

The above examples assume that ECC data is computed based on rows and columns, as specified in several optical disk standards. However, the ECC data in an auxiliary ECC block does have to conform to optical disk standards. That is, the format of an auxiliary ECC block preferably conforms to standards, but the ECC data within the primary data area of an auxiliary ECC block can be different than what is specified by the standards. For example, the ECC data can be computed based on diagonal lines instead of rows and columns. If there is a cluster of errors resulting in multiple uncorrectable errors in rows and columns, using diagonal lines may result in a correctable number of errors in each diagonal line.

In some multi-level ECC algorithms, if a first level of correction determines that a group of bytes is defective and uncorrectable, the first level “erases” the group of bytes by setting all bytes to a value assigned to be a erasure symbol. The next level of correction is then capable of correcting some number of erasures in addition to some number of defective bytes. In one alternative embodiment, when auxiliary ECC blocks are used only when errors cannot be corrected by a primary ECC block, the error correction in the primary ECC block erases all uncorrectable rows, then erases all uncorrectable columns, and then applies ECC data in the auxiliary ECC block to the resulting data with erasures.

Auxiliary ECC blocks occupy space that normally would be occupied by primary ECC blocks. Accordingly, auxiliary ECC blocks decrease the data capacity of a medium. If the ECC data in the primary ECC blocks is independent of the ECC data in the auxiliary ECC blocks, then auxiliary ECC blocks can be overwritten if additional capacity is needed. If independent, the ECC data in the primary ECC block is still available even if the auxiliary ECC block is not available (defective or overwritten). One example of usage is to use an auxiliary ECC block only if an associated primary ECC block is not capable of correcting an error. Of course, there is some finite probability that an error in a primary ECC block can remain undetected, so additional data integrity assurance can be obtained by using only an auxiliary ECC block, if available.

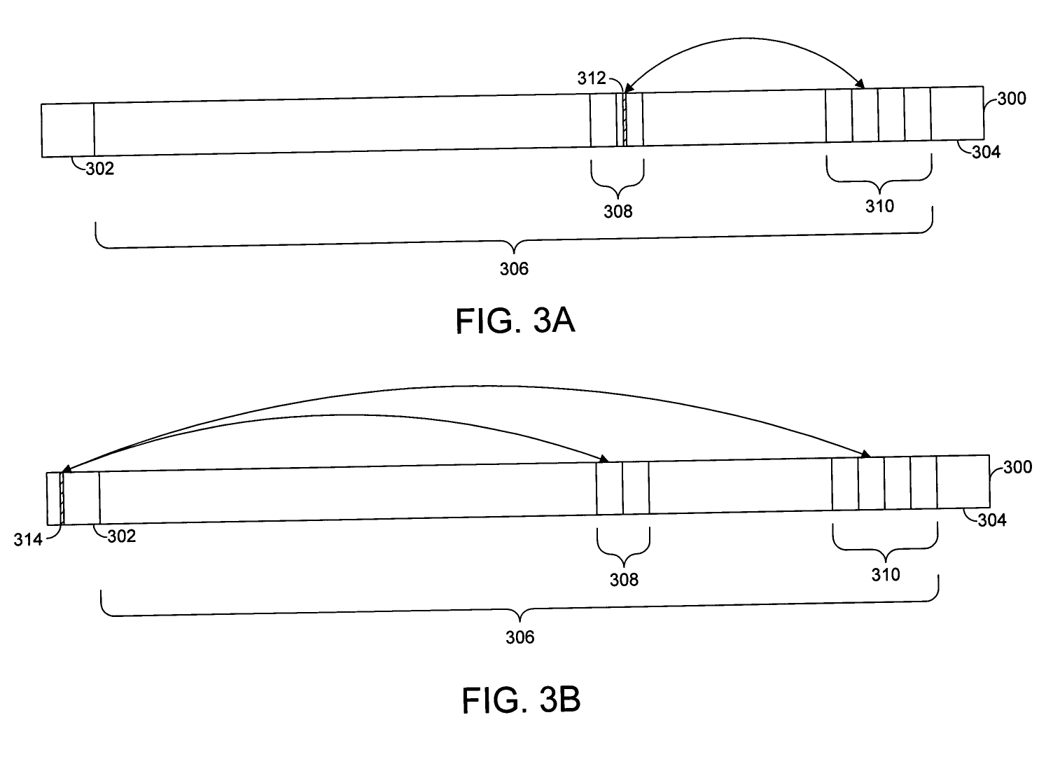

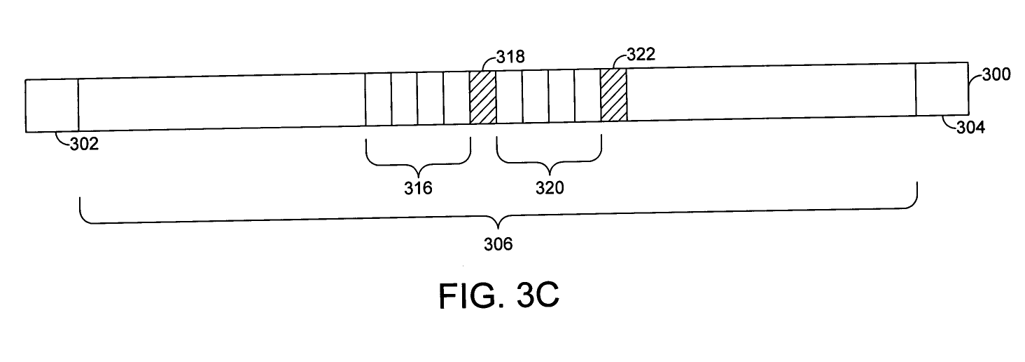

FIGS. 3A-3C illustrate an example of a track 300 on an optical disk, including auxiliary ECC blocks. Optical disks (such as data CD and DVD) commonly have a reserved area at the beginning of a track, called a lead-in area (302), and a reserved area at the end of the track, called a lead-out area (304). Everything between lead-in and lead-out is available for data (306). The lead-in and lead-out areas typically include a data structure specifying physical locations of sectors or blocks. The lead-in and lead-out areas may also include control structures for sectors or blocks. Logical file directories are typically in the data area. In FIG. 3A, primary ECC blocks 308 are in the area available for data. Auxiliary ECC blocks may be placed at an end of a data area, so that they remain undisturbed unless additional data capacity is required. In FIGS. 3A and 3B, auxiliary ECC blocks 310 have been placed at the end of the data area 306.

Alternatively, auxiliary ECC blocks may be placed at regular intervals among the primary ECC blocks. For example, every fifth ECC block may be an auxiliary ECC block, or every ninth and tenth ECC block may be auxiliary ECC blocks, and so forth. In FIG. 3C, auxiliary ECC blocks 318 have been placed at regular intervals among the primary ECC blocks 316 and 320.

Not all primary ECC blocks need an auxiliary ECC block. That is, only selected primary data may need additional assurance of data integrity. Preferably, for each primary ECC block, there is an indication as to whether there is an associated auxiliary ECC block. The indication may be within each primary ECC block, or may be within a separate data structure or control structure, or may be inherent in a format (auxiliary ECC blocks in fixed locations, or fixed locations relative to associated primary ECC blocks). The indication may simply be one bit that indicates that an associated auxiliary ECC block exists, or the indication may include an address or pointer to an associated auxiliary ECC block. In FIG. 3A, a data field 312, within a primary ECC block, indicates the block address of an associated auxiliary ECC block. In the example of FIG. 3B, a data field 314, within a data structure or other disk information in the lead-in area, associates a primary ECC block with an auxiliary ECC block. Alternatively, one or more bits within some or all sectors of the primary ECC blocks may be concatenated to create an absolute or relative address for the auxiliary ECC block. For example, with 16 sectors per ECC block, one bit per sector can provide a 16-bit address for an associated auxiliary ECC block.

In FIG. 3C, auxiliary ECC blocks are distributed among the primary ECC blocks. A first group of four primary ECC blocks 316 has an associated auxiliary ECC block 318, and a second group of four primary ECC blocks 320 has an associated auxiliary ECC block 322. Either of the indication options illustrated in FIGS. 3A and 3B may be used to associate primary ECC blocks with auxiliary ECC blocks in FIG. 3C. Alternatively, with a fixed ratio (for example, every fifth ECC block is an auxiliary ECC block), then association is built into the format and no separate indication is needed. In FIG. 3C, auxiliary ECC blocks are after the associated primary ECC blocks, but they could alternatively be ahead of the associated primary ECC blocks, and may be written first.

If the ECC data in the primary EEC block and the auxiliary ECC block are independent, then a medium written as illustrated in any of FIGS. 3A-3C can be read by a system that has no knowledge of the auxiliary ECC data. That is, the primary ECC blocks may be read, and the ECC data within the primary ECC blocks may be used for error correction, with no reference to any auxiliary ECC block. Accordingly, additional data integrity can be provided for compatible systems, while maintaining read compatibility in other systems.

Since auxiliary ECC blocks are written separately from primary ECC blocks, it is possible for a primary ECC block to indicate an associated auxiliary ECC block, where the associated auxiliary ECC block may be defective or missing (power loss or other problem during writing, or later overwritten). An indication associating a primary ECC block with an auxiliary ECC block may be written after the auxiliary ECC block is successfully written. Alternatively, an auxiliary ECC block may be written before the associated primary ECC block. Alternatively, one or more matching bits may be written within the primary and associated auxiliary ECC blocks, and the bits may be required to match or an error will be assumed. Alternatively, a primary ECC block (or directory or control structure) may include an indication that an auxiliary ECC block will be written, and the indication may then be cleared or altered after the auxiliary ECC block is successfully written. In addition, if an auxiliary ECC block is overwritten, preferably any pointers or indicators associating the auxiliary ECC block with one or more primary ECC blocks should be cleared.

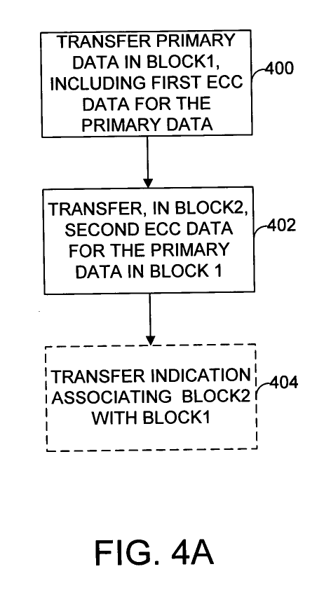

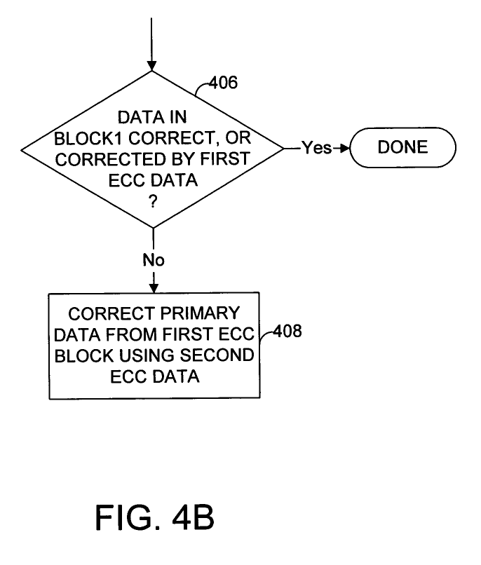

FIG. 4A illustrates an example method for writing data on a medium. At step 400, a first ECC block is transferred (read, written, received, or transmitted). At step 402, a second ECC block is transferred that includes ECC data for the first ECC block. At step 404, which is optional, an indication is transferred that associates the second ECC block with the first ECC block. Steps 400, 402, and 404 may be performed in any order. In addition, step 404 may be included in step 400 or step 402.

When reading or receiving data, a system may choose to always use the second ECC data on the primary data in the first ECC block, ignoring the first ECC data. However, always processing two blocks may impact performance. Alternatively, a system may always first try to use the first ECC data, and then read and use the second ECC data only when the first ECC data cannot correct an error. This alternative is illustrated in FIG. 4B. At step 406, if the data in the first ECC block is correct, or if the data in the first ECC block has been successfully corrected by the first ECC data, then the second ECC data is not needed. At step 408, the first ECC data has failed to correct an error, and the second ECC data is used.

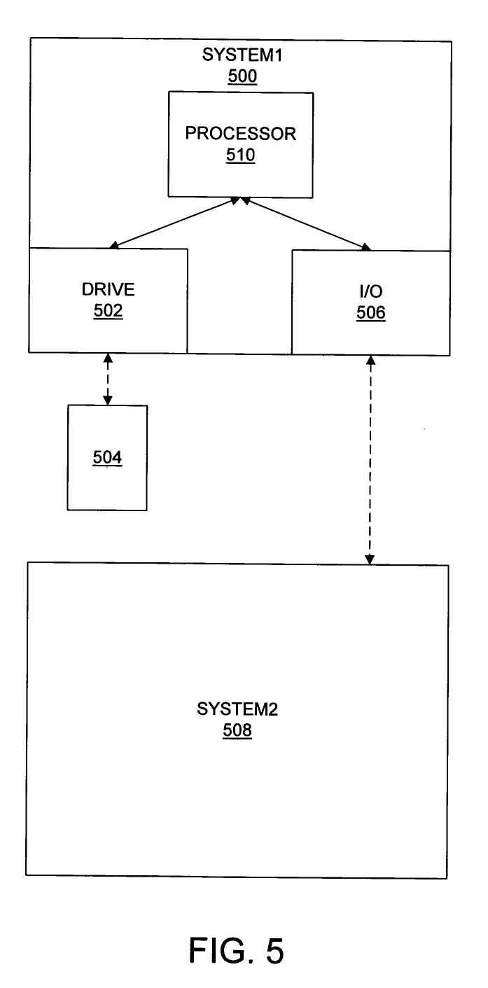

FIG. 5 illustrates an example system. In FIG. 5, a first system 500 may include a drive 502. A data medium 504 may be captive within the drive (for example, a hard disk), or removable (for example, DVD). The data tracks illustrated by FIGS. 3A-3B may be recorded on the data medium 504 by the drive 502. The method of FIG. 4 may be implemented by drive 502 when recording on the data medium 504. Alternatively, or in addition, data logically formatted into ECC blocks as illustrated in FIG. 1, but with auxiliary ECC blocks, may be communicated (received or transmitted), by an I/O system 506, between the first system 500 to a second system 508. The communication may occur over wires, optical cable, or wirelessly. The first system 500 may be any system that stores, reads, writes, records, receives, or transmits data, for example, but not limited to, a computer, a server, a workstation, a digital appliance, an entertainment system, a cell phone, or a digital camera. The drive or first system may include a processor 510 that performs the method of FIG. 4. Alternatively, drive 502 or I/O system 506 may include a processor that performs the method of FIG. 4.

1. A data storage medium, comprising:
primary data, logically formatted into a first block, the first block including first error correction codes for the primary data; and
a second block, the second block including second error correction codes for the primary data in the first block.

2. The data storage medium of claim 1, further comprising:
the second block including third error correction codes for the second error correction codes.

3. The data storage medium of claim 1, further comprising:
the first block including an indication that associates the second block with the first block.

4. The data storage medium of claim 1, further comprising:
a data structure identifying physical locations of data; and
an indication in the data structure that associates the second block with the first block.

5. The data storage medium of claim 1, further comprising:
a data area, the data area having a beginning and an end, the first block within the data area, and the second block near the end of the data area.

6. The data storage medium of claim 1, further comprising:
a plurality of blocks containing primary data;
a plurality of blocks containing error correction codes for the primary data; and
the blocks containing error correction codes distributed among the blocks containing primary data.

7. The data storage medium of claim 1, further comprising:
the first error correction codes and the second error correction codes provide independent correction of the primary data.

8. A method, comprising:
transferring primary data in a first block;
transferring, in the first block, first error correction codes for the primary data in the first block;
transferring, in a second block, second error correction codes for the primary data in the first block.

9. A method, comprising:
writing primary data in a first block;
writing, in the first block, first error correction codes for the primary data in the first block;
writing, in a second block, second error correction codes for the primary data in the first block.

10. The method of claim 9, further comprising:
writing an indication associating the second block with the first block.

11. The method of claim 10, further comprising:
writing the second block before writing the indication.

12. The method of claim 10, further comprising:
clearing the indication when the second block is overwritten.

13. The method of claim 9, further comprising:
writing, before the second block is written, an indication that the second block will be written; and
clearing, the indication, after the second block is written.

14. A method, comprising:
reading primary data in a first ECC block;
applying error correction data, from a second ECC block, to the primary data.

15. The method of claim 14, further comprising:
applying error correction data, from the first ECC block, to the primary data; and
applying the error correction data from the second ECC block, to the primary data, when the error correction data from the first ECC block fails to correct an error.

16. The method of claim 15, further comprising:
erasing uncorrectable data in the first ECC block before applying the error correction data from the second ECC block.

17. A system, comprising:
means for communicating primary data formatted into in a first block;
means for communicating, in the first block, first error correction codes for the primary data;
means for communicating, in a second block, second error correction codes for the primary data in the first block.

18. A system, comprising:
a processor, the processor programmed to perform the following method:
transferring primary data in a first block;
transferring, in the first block, first error correction codes for the primary data in the first block;
transferring, in a second block, second error correction codes for the primary data in the first block.
